(19) United States
(12) Patent Application Publication
(10) Pub. No.: US 2010/0221918 A1
(43) Pub. Date: Sep. 2, 2010

(54) AQUEOUS DISPERSION FOR CHEMICAL MECHANICAL POLISHING AND METHOD FOR PREPARING THE SAME, KIT FOR PREPARING AQUEOUS DISPERSION FOR CHEMICAL MECHANICAL POLISHING, AND CHEMICAL MECHANICAL POLISHING METHOD FOR SEMICONDUCTOR DEVICE

(75) Inventors: Akihiro Takemura, Mie (JP); Mitsuru Meno, Mie (JP); Yuuji Shimoyama, Ibaraki (JP); Hirotaka Shida, Mie (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: JSR Corporation, Tokyo (JP)

(21) Appl. No.: 12/676,272

(22) PCT Filed: Aug. 12, 2008
(86) PCT No.: PCT/JP2008/064465

§ 371 Date: May 3, 2010

(30) Foreign Application Priority Data
Sep. 3, 2007 (JP) 2007-227573

(51) Int. Cl. H01L 21/304; H01L 21/306; C09K 13/00

(52) U.S. Cl. 438/693; 252/79.1; 257/E21.23

(57) ABSTRACT

A chemical mechanical polishing aqueous dispersion includes (A) a sulfonic acid group-containing water-soluble polymer, (B) an amino acid, (C) abrasive grains, and (D) an oxidizing agent.

### TECHNICAL FIELD

The present invention relates to a chemical mechanical polishing aqueous dispersion, a method of preparing the same, a chemical mechanical polishing aqueous dispersion preparation kit, and a chemical mechanical polishing method for a semiconductor device.

### BACKGROUND ART

A copper damascene interconnect provided in a high-performance LSI is formed by chemical mechanical polishing (hereinafter may be referred to as “CMP”). CMP includes a first polishing step that mainly polishes copper, and a second polishing step that polishes unnecessary metal and an insulating film. In the first polishing step, the copper film must be polished at a high speed while reducing dishing without substantially polishing a barrier metal film formed of Ta or Ti. When using a low-k material as the material for the insulating film, delamination or destruction of the film may occur if a polishing friction occurs to a large extent. Therefore, it may be difficult to apply a chemical mechanical polishing aqueous dispersion (hereinafter may be referred to as “CMP slurry”) that causes a large polishing friction.

In the second polishing step, it is desirable to implement low-friction polishing to increase the hydrophilicity of the polishing substrate surface and the abrasive cloth so that scratches and corrosion of copper and scratches of the insulating film are reduced while reducing dishing of copper and erosion of the insulating film. Since a silicone-containing surfactant that has been added to a CMP slurry strongly acts on silica (abrasive grains) to produce large particles, it has been difficult to reduce scratches and stabilize the removal rate.

In order to satisfy the requirements for the first polishing step and the second polishing step, JP-A-2003-282494, JP-A-2002-270549, and JP-T-2002-517593 disclose a CMP slurry that utilizes polyvinylpyrrolidone (PVP). JP-A-2005-340755 discloses a polishing composition and a polishing method that reduces dishing and erosion by increasing affinity with a copper interconnect using a vinylpyrrolidone-vinylimidazole copolymer obtained by polymerizing vinylpyrrolidone and a vinyl group-containing azole compound.

In recent years, it has been desired to further reduce dishing and corrosion of copper and scratches of the insulating film along with a reduction in size of interconnects. In particular, it is necessary to reduce dishing of copper to 400 angstroms or less. An increase in removal rate is also desired from the viewpoint of increasing throughput. Specifically, a removal rate of 8000 angstroms/min or more is desired without producing residual copper after polishing. It is difficult to meet the above requirements using a CMP slurry that utilizes polyvinylpyrrolidone or a CMP slurry that utilizes a vinylpyrrolidone-vinylimidazole copolymer. Therefore, development of a CMP slurry that can achieve a high removal rate and planarization of a polishing substrate surface required for CMP of next-generation LSI has been desired.

### DISCLOSURE OF THE INVENTION

An object of the invention is to provide a chemical mechanical polishing aqueous dispersion that can uniformly and stably polish a metal film with a low friction while achieving a high removal rate and excellent planarity without causing defects in the metal film and the insulating film, a kit for preparing the dispersion, a method of preparing a chemical mechanical polishing aqueous dispersion using the kit, and a chemical mechanical polishing method for a semiconductor device.

According to the invention, there is provided a chemical mechanical polishing aqueous dispersion comprising (A) a sulfonic acid group-containing water-soluble polymer, (B) an amino acid, (C) abrasive grains, and (D) an oxidizing agent.

The chemical mechanical polishing aqueous dispersion according to the invention may further comprise (E) an anionic surfactant.

In the chemical mechanical polishing aqueous dispersion according to the invention, the sulfonic acid group-containing water-soluble polymer (A) may be a copolymer that contains a repeating unit derived from a sulfonic acid group-containing monomer and a repeating unit derived from an amide group-containing monomer.

In the chemical mechanical polishing aqueous dispersion according to the invention, the sulfonic acid group-containing monomer may be selected from isoprenesulfonic acid, styrenesulfonic acid, vinylsulfonic acid, allylsulfonic acid, methallylsulfonic acid, 3-sulfopropyl acrylate, 3-sulfopropyl methacrylate, 2-acrylamide-methylpropanesulfonic acid, and salts thereof.

In the chemical mechanical polishing aqueous dispersion according to the invention, the amide group-containing monomer may be selected from (meth)acrylamide, N-methylolacrylamide, N-2-hydroxyethylacrylamide, acryloylmorpholine, dimethylaminopropylacrylamide, N,N-dimethylacrylamide, N-isopropylacrylamide, N-vinylacetamide, and N-vinylformamide.

In the chemical mechanical polishing aqueous dispersion according to the invention, the sulfonic acid group-containing water-soluble polymer (A) may have a weight average molecular weight of 5000 to 500,000.

According to the invention, there is provided a chemical mechanical polishing aqueous dispersion preparation kit comprising a first composition and a second composition, the first composition including (C) abrasive grains, the second composition including (A) a sulfonic acid group-containing water-soluble polymer and (B) an amino acid, and at least one of the first composition and the second composition including (D) an oxidizing agent.

According to the invention, there is provided a chemical mechanical polishing aqueous dispersion preparation kit comprising a third composition, a fourth composition, and a fifth composition, the third composition including (C) abrasive grains, the fourth composition including (A) a sulfonic acid group-containing water-soluble polymer and (B) an amino acid, and the fifth composition including (D) an oxidizing agent.

According to the invention, there is provided a method of preparing a chemical mechanical polishing aqueous dispersion, the method comprising mixing the compositions of the above chemical mechanical polishing aqueous dispersion preparation kit.

According to the invention, there is provided a chemical mechanical polishing method for a semiconductor device, the method comprising polishing a copper or copper alloy film formed on a semiconductor substrate by using the above chemical mechanical polishing aqueous dispersion or a chemical mechanical polishing aqueous dispersion prepared by mixing the compositions of the above chemical mechanical polishing aqueous dispersion preparation kit.

When performing chemical mechanical polishing using the above chemical mechanical polishing aqueous dispersion, a metal film can be uniformly and stably polished with a low friction while achieving a high removal rate and excellent planarity without causing defects in the metal film and the insulating film. The above chemical mechanical polishing aqueous dispersion may be useful as a polishing agent used in a first polishing step when the metal film is a copper film and a two-stage polishing process is performed by using a damascene method. This makes it possible to reduce residual copper after chemical mechanical polishing while highly reducing dishing, erosion, and corrosion of the copper film.

According to the above chemical mechanical polishing aqueous dispersion preparation kit, since the components of the chemical mechanical polishing aqueous dispersion can be separately stored as different compositions, the storage stability of each component can be improved. Since the chemical mechanical polishing aqueous dispersion can be prepared by mixing and diluting the compositions before use, a constant polishing performance is necessarily achieved.

### BRIEF DESCRIPTION OF THE DRAWINGS

FIG. 1A is a cross-sectional view of a polishing substrate illustrating a specific example of a chemical mechanical polishing method.

FIG. 1B is a cross-sectional view of a polishing substrate illustrating a specific example of a chemical mechanical polishing method.

FIG. 1C is a cross-sectional view of a polishing substrate illustrating a specific example of a chemical mechanical polishing method.

FIG. 2 is a schematic view illustrating a chemical mechanical polishing apparatus.

### BEST MODE FOR CARRYING OUT THE INVENTION

Preferred embodiments of the invention are described in detail below.

### 1. Chemical Mechanical Polishing Aqueous Dispersion

A chemical mechanical polishing aqueous dispersion according to one embodiment of the invention includes (A) a sulfonic acid group-containing water-soluble polymer, (B) an amino acid, (C) abrasive grains, and (D) an oxidizing agent. Each component of the chemical mechanical polishing aqueous dispersion according to this embodiment is described in detail below.

### 1.1 Sulfonic Acid Group-Containing Water-Soluble Polymer (A)

The term “sulfonic acid group” used in connection with the invention also includes a sulfonate group (e.g., —SO₃Na and —SO₃K) obtained by replacing a hydrogen atom of a sulfonic acid group with a metal atom (e.g., alkali metal).

Examples of the sulfonic acid group-containing water-soluble polymer (A) used in this embodiment include polystyrenesulfonic acid, polyallylsulfonic acid, polymethallylsulfonic acid, polyvinylsulfonic acid, polyisoprenesulfonic acid, a 3-sulfopropyl acrylate homopolymer, a 3-sulfopropyl methacrylate homopolymer, 2-hydroxy-3-acrylamidepropanesulfonic acid homopolymer, and salts thereof.

The water-soluble polymer may be a homopolymer, or may be a copolymer that contains a repeating unit derived from a sulfonic acid group-containing monomer and a repeating unit derived from a monomer that contains a functional group other than a sulfonic acid group. The monomer that contains a functional group other than a sulfonic acid group is preferably an amide group-containing monomer, but may be a carboxyl group-containing monomer, a hydroxyl group-containing monomer, a monomer having a polyethylene oxide chain, an amino group-containing monomer, a monomer having a heterocyclic ring, or the like. When the water-soluble polymer is a copolymer that contains a repeating unit derived from a sulfonic acid group-containing monomer and a repeating unit derived from a monomer that contains a functional group other than a sulfonic acid group, the water-soluble polymer exhibits improved water solubility or affinity to a metal (e.g., copper).

Examples of the sulfonic acid group-containing monomer include isoprenesulfonic acid, styrenesulfonic acid, vinylsulfonic acid, allylsulfonic acid, methallylsulfonic acid, 3-sulfopropyl acrylate, 3-sulfopropyl methacrylate, 2-acrylamide-methylpropanesulfonic acid, salts thereof, and the like.

Examples of the amide group-containing monomer include (meth)acrylamide, N-methylolacrylamide, N-2-hydroxyethylacrylamide, acryloylmorpholine, dimethylaminopropylacrylamide, N,N-dimethylacrylamide, N-isopropylacrylamide, N-vinylacetamide, N-vinylformamide, and the like.

Examples of the carboxyl group-containing monomer include acrylic acid, methacrylic acid, itaconic acid, maleic acid, fumaric acid, salts thereof, and the like. These acids may be used in the form of an acid anhydride.

Examples of the hydroxyl group-containing monomer include vinyl alcohol, allyl alcohol, hydroxyethyl(meth)acrylate, polyethylene glycol mono(meth)acrylate, polypropylene glycol mono(meth)acrylate, vinylglycolic acid, and the like. The alkyl side chain length and the ethylene oxide side chain length are not particularly limited.

Examples of the amino group-containing monomer include N,N-dimethylaminoethyl(meth)acrylate, dimethylaminopropylacrylamide, and the like. The alkyl side chain length is not particularly limited. These compounds may be a quaternized salt obtained by using a cationizing agent.

Examples of the monomer having a heterocyclic ring include vinylimidazole, vinylpyrrolidone, vinylpyridine, vinyloxazoline, N-vinylcaprolactam, vinylpyrrole, vinylquinoline, and the like.

A commercially available surfactant that contains a polymerizable double bond and a sulfonic acid group in the molecule may also be used as the monomer. Examples of such a surfactant include Eleminol JS-2 (manufactured by Sanyo Chemical Industries, Ltd.), Latemul ASK (manufactured by Kao Corporation), and the like.

Examples of other monomers include aromatic vinyl compounds such as styrene, alpha-methylstyrene, vinyltoluene, and p-methyl styrene; aliphatic conjugated dienes such as butadiene, isoprene, 2-chloro-1,3-butadiene, and 1-chloro-1,3-butadiene; vinyl cyanide compounds such as (meth)acrylonitrile; cyclohexyl(meth)acrylate, phosphoric acid compounds, and the like. These monomers may be used either individually or in combination.

The sulfonic acid group-containing water-soluble polymer (A) may be blended with a water-soluble polymer obtained by polymerizing the above-mentioned monomers that do not contain a sulfonic acid group, or may be blended with other synthetic polymers or natural polymers. Examples of such polymers include polyvinyl alcohol, polyethylene oxide, polyethylenimine, hydroxyethyl cellulose, carboxymethyl cellulose, methyl cellulose, sodium alginate, casein, chitin, chitosan, cyclodextrin, modified starch, and the like.

The sulfonic acid group-containing water-soluble polymer (A) may be produced by the following method, for example. Specifically, the monomers are normally polymerized at 50 to 100° C., and preferably 60 to 90° C. for 0.1 to 20 hours, and preferably 1 to 15 hours in the presence of an initiator (e.g., hydrogen peroxide, organic peroxide, persulfate, or azo compound) to obtain a polymer (copolymer). The monomers may be polymerized while successively adding the monomers (stepwise polymerization). The term “stepwise polymerization” used herein refers to supplying the monomers to the polymerization system without changing the amount of monomers supplied per unit time or while changing the amount of monomers supplied per unit time.

A polymerization solvent may be used so that the reaction proceeds smoothly. As the polymerization solvent, water, a mixture of water and an organic solvent that is miscible with water, or the like may be used. Examples of the organic solvent include tetrahydrofuran, 1,4-dioxane, alcohols, and the like. Note that the organic solvent is not particularly limited insofar as the organic solvent is miscible with water.

The polyethylene glycol-reduced weight average molecular weight of the sulfonic acid group-containing water-soluble polymer determined by gel permeation chromatography (GPC) is preferably 5000 to 500,000, and more preferably 5000 to 100,000. If the average molecular weight of the sulfonic acid group-containing water-soluble polymer is within the above range, abrasive grains are uniformly dispersed in the resulting CMP slurry so that a metal film can be polished in a stable manner. If the average molecular weight of the sulfonic acid group-containing water-soluble polymer is less than the lower limit, the resulting CMP slurry may not sufficiently protect a metal film so that planarity may deteriorate, or occurrence of corrosion may not be reduced. If the average molecular weight of the sulfonic acid group-containing water-soluble polymer is greater than the upper limit, the abrasive grains may not sufficiently come in contact with the metal film, so that a practical removal rate may not be achieved. Moreover, the abrasive grains may aggregate in a slurry supply apparatus so that the number of scratches produced on the metal film may increase.

The content of the water-soluble polymer is preferably 0.001 to 1.0 mass %, more preferably 0.01 to 1.0 mass %, and particularly preferably 0.02 to 0.5 mass %, based on the total mass of the chemical mechanical polishing aqueous dispersion. If the content of the water-soluble polymer is less than 0.001 mass %, corrosion may not be sufficiently reduced. If the content of the water-soluble polymer is greater than 2.0 mass %, a practical metal film removal rate may not be achieved so that unnecessary metal (e.g., copper) may remain.

The water-soluble polymer is not limited to a polymer obtained by polymerizing monomers. For example, the water-soluble polymer may be a sulfonic acid group-containing condensate. Examples of the sulfonic acid group-containing condensate include a naphthalene sulfonic acid formalin condensate, a condensate of sulfonic acid group-containing phenol, naphthol, and formalin, a melamine sulfonic acid condensate, and the like.

### 1.2 Amino Acid (B)

The amino acid (B) used in this embodiment increases the removal rate. In particular, the amino acid (B) increases the removal rate for a wiring material formed of copper or a copper alloy.

The amino acid (B) is preferably an amino acid that can be coordinated to an ion of an element that forms the wiring material or the surface of the wiring material. The amino acid (B) is more preferably an amino acid that can be chelate-coordinated to an ion of an element that forms the wiring material or the surface of the wiring material. Specific examples of the amino acid (B) include glycine, alanine, lysine, arginine, phenylalanine, histidine, cysteine, methionine, glutamic acid, aspartic acid, glutamic acid, thyrosin, leucine, tryptophan, and the like. It is preferable to use glycine as the amino acid (B) since the removal rate is particularly increased. The amino acid (B) may be used either individually or in combination.

The amino acid (B) can be easily coordinated to copper ions dissolved in the chemical mechanical polishing aqueous dispersion when polishing the copper film so that the surface of the copper film can be appropriately protected during polishing. The amino acid (B) thus reduces polishing defects (e.g., scratches or surface roughness). The sulfonic acid group-containing water-soluble polymer (A) used in the invention may adhere to the surface of the copper film and hinder polishing (decrease the removal rate) depending on the type and the amount of the sulfonic acid group-containing water-soluble polymer (A). However, the removal rate of the copper film can be increased by utilizing the amino acid in combination with the sulfonic acid group-containing water-soluble polymer (A).

The content of the amino acid (B) is preferably 0.01 to 5 mass %, and more preferably 0.05 to 2 mass %, based on the total mass of the chemical mechanical polishing aqueous dispersion. If the content of the amino acid is less than 0.01 mass %, a practical removal rate may not be achieved. If the content of the amino acid is more than 5 mass %, planarity may deteriorate.

### 1.3 Abrasive Grains (C)

The abrasive grains (C) used in this embodiment are preferably inorganic particles or organic-inorganic composite particles.

Examples of the inorganic particles include fumed silica, fumed alumina, and fumed titania synthesized by reacting silicon chloride, aluminum chloride, titanium chloride, or the like with oxygen and hydrogen in a gas phase using a fuming method; silica synthesized by subjecting a metal alkoxide to hydrolysis and condensation using a sol-gel method; high-purity colloidal silica which is synthesized by an inorganic colloid method or the like and from which impurities have been removed by purification; and the like.

The type and the configuration of the organic-inorganic composite particles are not particularly limited insofar as inorganic particles and organic particles as mentioned above are integrally formed in such a manner that the inorganic particles and the organic particles are not easily separated during polishing. Examples of the organic-inorganic composite particles include composite particles obtained by subjecting an alkoxysilane, an aluminum alkoxide, a titanium alkoxide, or the like to polycondensation in the presence of polymer particles (e.g., polystyrene or polymethyl methacrylate) so that a polycondensate (e.g., polysiloxane, polyaluminoxane, or polytitanoxane) is formed on at least the surface of the polymer particles. The polycondensate may be directly bonded to a functional group of the polymer particle, or may be indirectly bonded to a functional group of the polymer particle through a silane coupling agent or the like.

The organic-inorganic composite particles may be formed by using the polymer particles and silica particles, alumina particles, titania particles, or the like. In this case, the composite particles may be formed so that silica particles or the like are present on the surface of the polymer particles using a polycondensate (e.g., polysiloxane, polyaluminoxane, or polytitanoxane) as a binder, or may be formed so that functional groups (e.g., hydroxyl groups) of silica particles or the like are chemically bonded to functional groups of the polymer particles.

As the organic-inorganic composite particles, composite particles in which organic particles and inorganic particles having zeta potentials of opposite polarities (positive or negative) are bonded by an electrostatic force in an aqueous dispersion containing these particles, may be used.

The zeta potential of organic particles is generally negative over the entire pH range or a wide pH range excluding a low pH range. When organic particles have a carboxyl group, a sulfonic acid group, or the like, the organic particles more reliably have a negative zeta potential. When organic particles have an amino group or the like, the organic particles have a positive zeta potential in a given pH range.

The zeta potential of inorganic particles has high pH dependence. Inorganic particles have an isoelectric point at which the zeta potential is zero, and the polarity of the zeta potential is reversed across the isoelectric point.

Therefore, when mixing specific organic particles and inorganic particles in a pH range in which the organic particles and the inorganic particles have zeta potentials of opposite polarities, the organic particles and the inorganic particles are bonded by an electrostatic force to form composite particles. Even if the organic particles and the inorganic particles have zeta potentials of the same polarity when mixed, the organic particles and the inorganic particles may be bonded by reversing the polarity of the zeta potential of either the organic particles or the inorganic particles (particularly the inorganic particles) by changing the pH of the mixture.

A polycondensate (e.g., polysiloxane, polyaluminoxane, or polytitanoxane) may be formed on at least the surface of the composite particles integrated by an electrostatic force by subjecting an alkoxysilane, an aluminum alkoxide, a titanium alkoxide, or the like to polycondensation in the presence of the composite particles.

The average particle diameter of the abrasive grains (C) is preferably 5 to 1000 nm. The average particle diameter of the abrasive grains may be measured by using a laser scattering diffraction measuring instrument or observation using a transmission electron microscope. If the average particle diameter of the abrasive grains is less than 5 nm, a chemical mechanical polishing aqueous dispersion that achieves a sufficiently high removal rate may not be obtained. If the average particle diameter of the abrasive grains is more than 1000 nm, dishing and erosion may not be reduced sufficiently. Moreover, a stable chemical mechanical polishing aqueous dispersion may not be obtained due to precipitation/separation of the abrasive grains. The average particle diameter of the abrasive grains is more preferably 10 to 700 nm, and particularly preferably 15 to 500 nm. If the average particle diameter of the abrasive grains is within the above range, a stable chemical mechanical polishing aqueous dispersion which achieves a high removal rate, sufficiently reduces dishing and erosion, and rarely shows precipitation/separation of the abrasive grains can be obtained. The abrasive grains may be used either individually or in combination.

The content of the abrasive grains (C) is preferably 0.01 to 5 mass %, and more preferably 0.01 to 2 mass %, based on the total mass of the chemical mechanical polishing aqueous dispersion. If the content of the abrasive grains is less than 0.01 mass %, a sufficient removal rate may not be achieved. If the content of the abrasive grains is more than 5 mass %, cost may increase. Moreover, a stable chemical mechanical polishing aqueous dispersion may not be obtained.

### 1.4 Oxidizing Agent (D)

The oxidizing agent (D) used in this embodiment oxidizes the surface of the polishing substrate surface (i.e., forms a brittle state) so that the polishing substrate surface can be easily polished.

Examples of the oxidizing agent (D) include ammonium persulfate, potassium persulfate, hydrogen peroxide, ferric nitrate, cerium diammonium nitrate, iron sulfate, ozone, potassium periodate, peracetic acid, and the like. These oxidizing agents may be used either individually or in combination. Among these oxidizing agents, ammonium persulfate, potassium persulfate, and hydrogen peroxide are particularly preferable from the viewpoint of oxidizing power, compatibility with a protective film, handling capability, and the like. The content of the oxidizing agent (D) is preferably 0.01 to 5 mass %, and more preferably 0.05 to 2 mass %, based on the total mass of the chemical mechanical polishing aqueous dispersion. If the content of the oxidizing agent is less than 0.01 mass %, the surface of the metal film may not be sufficiently oxidized. As a result, the removal rate of the metal film may decrease. If the content of the oxidizing agent is more than 5 mass %, corrosion or dishing of the metal film (e.g., copper film) may occur to a large extent.

### 1.5 Anionic Surfactant (E)

It is preferable that the chemical mechanical polishing aqueous dispersion according to this embodiment further include (E) an anionic surfactant.

The anionic surfactant (E) is preferably an anionic surfactant that contains at least one functional group selected from a carboxyl group (—COOX), a sulfonic acid group (—SO₃X), and a phosphate group (—HPO₄X) (wherein X represents hydrogen, ammonium, or a metal).

Examples of the anionic surfactant (E) include an aliphatic soap, an aromatic sulfonate, an aliphatic sulfonate, an alkyl sulfate, and a phosphate salt, and the like. As such compounds, potassium dodecylbenzenesulfonate, ammonium dodecylbenzenesulfonate, sodium alkylnaphthalenesulphonate, alkyl sulfosuccinate (e.g., “Pelex OT-P” manufactured by Kao Corporation), potassium alkenylsuccinate (e.g., “Latemul ASK” manufactured by Kao Corporation), or the like may be preferably used. As the aliphatic soap, potassium oleate or the like may be preferably used. These anionic surfactants may be used either individually or in combination.

The content of the anionic surfactant (E) is preferably 0.001 to 1 mass %, and more preferably 0.01 to 0.5 mass %, based on the total mass of the chemical mechanical polishing aqueous dispersion. If the content of the anionic surfactant is within the above range, the (copper) dishing/erosion reduction effect of the water-soluble polymer can be improved. If the content of the anionic surfactant is less than 0.001 mass %, the effect of protecting the surface of the copper film may decrease (i.e., corrosion or excessive etching progresses) so that dishing or corrosion may occur to a large extent. If the content of the anionic surfactant is more than 1 mass %, the effect of protecting the surface of the copper film may increase to a large extent (i.e., a sufficient removal rate may not be achieved) so that copper may remain. Moreover, the silica particles may aggregate so that foaming may occur to a large extent.

### 1.6 Additives

### 1.6.1 Surfactant

The chemical mechanical polishing aqueous dispersion according to this embodiment may include a surfactant other than the anionic surfactant (E), if necessary. Examples of a surfactant other than the anionic surfactant (E) include a nonionic surfactant, a cationic surfactant, and the like.

Examples of the nonionic surfactant include a polyoxyethylene alkyl ether, an ethylene oxide-propylene oxide block copolymer, acetylene glycol, an ethylene oxide addition product of acetylene glycol, an acetylene alcohol, and the like. Note that a nonionic polymer compound such as polyvinyl alcohol, cyclodextrin, polyvinyl methyl ether, or hydroxyethylcellulose may also be used.

Examples of the cationic surfactant include an aliphatic amine salt, an aliphatic ammonium salt, and the like.

1.6.2 Acidic Compound

The chemical mechanical polishing aqueous dispersion according to this embodiment may include an acidic compound, if necessary. The acidic compound further increase the removal rate of a wiring material formed of copper or a copper alloy when used in combination with the amino acid (B).

As the acidic compound, an organic acid, an inorganic acid, or a salt thereof may be used. Examples of the acidic compound include organic acids such as citric acid, malic acid, oxalic acid, maleic acid, succinic acid, tartaric acid, pyrophosphoric acid, lactic acid, and benzoic acid; inorganic acids such as carbonic acid, nitric acid, sulfuric acid, and phosphoric acid; and ammonium salts and potassium salts thereof; and the like.

The total content of the acidic compound and the amino acid (B) is preferably 0.01 to 5 mass %, and more preferably 0.05 to 2 mass %, based on the total mass of the chemical mechanical polishing aqueous dispersion. If the total content of the acidic compound and the amino acid (B) is within the above range, the removal rate of a wiring material formed of copper or a copper alloy can be further increased.

1.7 pH

The pH of the chemical mechanical polishing aqueous dispersion according to this embodiment is preferably 8 to 11, and more preferably 9 to 10.5. If the pH of the chemical mechanical polishing aqueous dispersion is within the above range, corrosion of the metal film can be prevented without adding an anti-corrosion agent (e.g., benzotriazole or benzotriazole derivative). The pH of the chemical mechanical polishing aqueous dispersion may be adjusted by adding a basic compound such as potassium hydroxide, ammonia, ethylenediamine, or tetramethylammonium hydroxide (TMAH).

### 1.8 Application

The chemical mechanical polishing aqueous dispersion according to this embodiment may be mainly used as a polishing agent that chemically and mechanically polishes a copper film that forms interconnects of a semiconductor device. Specifically, the chemical mechanical polishing aqueous dispersion according to this embodiment may be used as a polishing agent for forming a copper (or copper alloy) damascene interconnect. A process of forming a copper (or copper alloy) damascene interconnect by chemical mechanical polishing includes a first polishing step that mainly removes copper (or copper alloy), and a second polishing step that mainly removes a conductive barrier metal film formed under the copper (or copper alloy). The chemical mechanical polishing aqueous dispersion according to this embodiment is effectively used for the first polishing step.

### 2. Chemical Mechanical Polishing Method

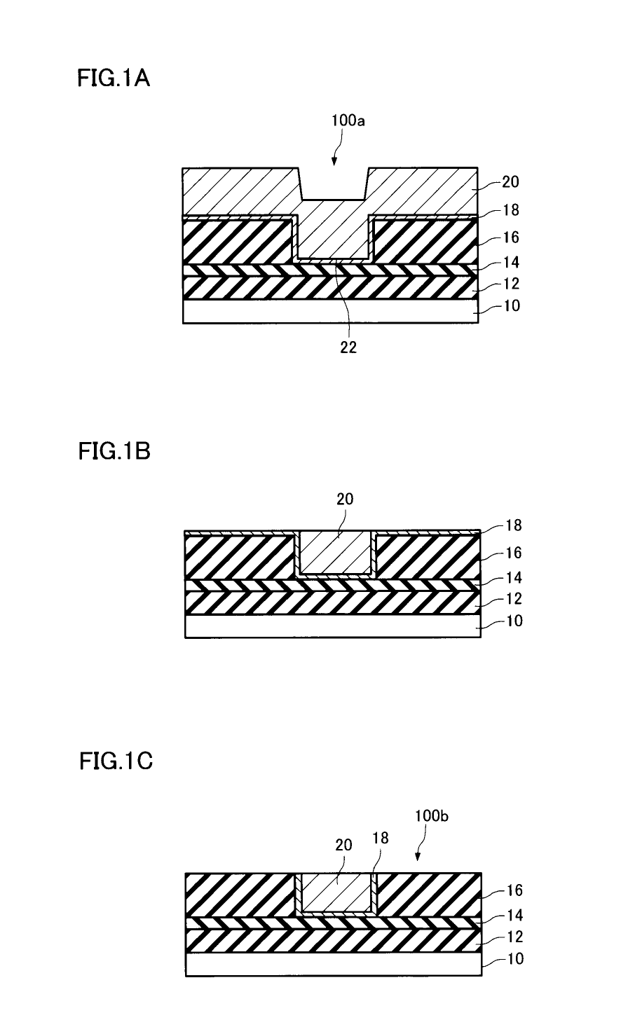

Each step of chemically and mechanically polishing a polishing substrate using the chemical mechanical polishing aqueous dispersion is described in detail below with reference to the drawings. FIGS. 1A to 1C are cross-sectional views schematically illustrating a specific example of the chemical mechanical polishing method.

### 2.1 Polishing Substrate

FIG. 1A illustrates a polishing substrate 100a. As illustrated in FIG. 1A, the polishing substrate 100a includes a substrate 10. The substrate 10 includes at least a semiconductor substrate (not illustrated). The substrate 10 may include a silicon substrate and a silicon oxide film formed on the silicon substrate, for example. A functional device such as a transistor may be formed on the semiconductor substrate included in the substrate 10.

The polishing substrate 100a includes an insulating film 12 (e.g., silicon oxide) formed on the substrate 10, an insulating film 14 (e.g., silicon nitride) formed on the insulating film 12, an insulating film 16 that is formed on the insulating film 14 and has an interconnect depression 22, a barrier metal film 18 that is formed to cover the surface of the insulating film 16 and the bottom and the inner wall surface of the interconnect depression 22, and a metal film 20 that is formed on the barrier metal film 18 so that the interconnect depression 22 is filled with the metal film 20.

Examples of the insulating film 16 include a silicon oxide film formed by a vacuum process (e.g., plasma enhanced TEOS (PETEOS) film, high-density plasma enhanced TEOS (HDP) film, or silicon oxide film formed by chemical vapor deposition), a fluorine-doped silicate glass (FSG) insulating film, a boron-phosphorus silicate glass (BPSG) film, a silicon oxynitride (SiON) insulating film, a silicon nitride film, a low-dielectric-constant insulating film, and the like.

The barrier metal film 18 may be formed of tantalum, tantalum nitride, titanium, titanium nitride, a tantalum-niobium alloy, or the like. The barrier metal film 18 is normally formed of one of these materials, but may be formed of two or more of these materials (e.g., tantalum and tantalum nitride).

As illustrated in FIG. 1A, the interconnect depression 22 must be completely filled with the metal film 20. In order to completely fill the interconnect depression 22 with the metal film 20, a metal film having a thickness of 10,000 to 15,000 angstroms is normally deposited by chemical vapor deposition or electroplating. Examples of the metal used for the metal film 20 include tungsten, aluminum, copper, and alloys thereof. The effects of the invention are most advantageously achieved when using copper or a copper alloy as the interconnect material. The copper content of the copper alloy is preferably 95 mass % or more.

### 2.2 Polishing Step

### 2.2.1 First Polishing Step

In the first polishing step, the metal film 20 of the polishing substrate 100a is polished by using the chemical mechanical polishing aqueous dispersion. In the first polishing step, the metal layer 20 is chemically and mechanically polished in an area other than the area positioned in the interconnect depression 22 until the barrier metal film 18 is exposed (see FIG. 1B).

Since the above chemical mechanical polishing aqueous dispersion can uniformly and stably polish a metal film with a low friction while achieving a high removal rate and excellent planarity without causing defects in the metal film and the insulating film, the above chemical mechanical polishing aqueous dispersion may be preferably used for the first polishing step.

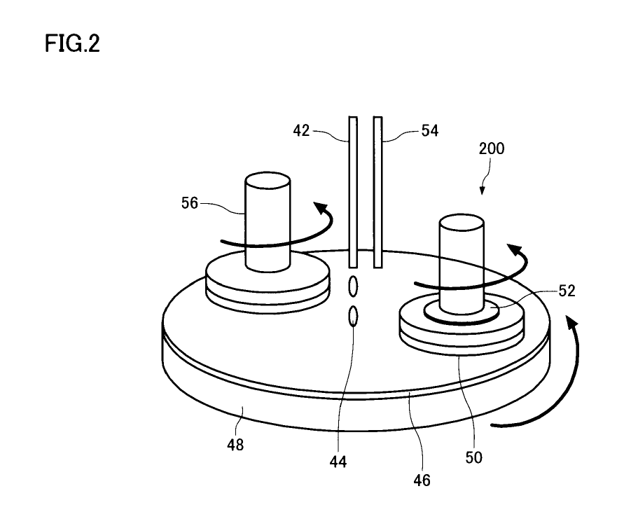

A chemical mechanical polishing apparatus 200 illustrated in FIG. 2 may be used in the first polishing step, for example. FIG. 2 is a schematic view illustrating the chemical mechanical polishing apparatus 200. A top ring 52 that holds a semiconductor substrate 50 is caused to come in contact with a turntable 48 to which an abrasive cloth 46 is attached while supplying a slurry 44 from a slurry supply nozzle 42 and rotating the turntable 48. FIG. 2 also illustrates a water supply nozzle 54 and a dresser 56.

The polishing load of the top ring 52 may be selected within the range of 10 to 1000 gf/cm², and is preferably 30 to 500 gf/cm². The rotational speed of the turntable 48 and the top ring 52 may be appropriately selected within the range of 10 to 250 rpm (preferably 30 to 150 rpm). The flow rate of the slurry 44 supplied from the slurry supply nozzle 42 may be selected within the range of 10 to 1000 cm³/min, and is preferably 50 to 400 cm³/min.

### 2.2.2 Second Polishing Step

In the second polishing step, the barrier metal film 18 of the polishing substrate 100a is polished by using a barrier metal film polishing slurry. Specifically, the barrier metal film 18 is polished until the insulating film 16 is exposed (see FIG. 1C). The barrier metal film 18 is thus removed in an area positioned at the bottom and the inner wall surface of the interconnect depression 22. A wiring structure 100b illustrated in FIG. 1C is thus obtained.

The chemical mechanical polishing apparatus 200 illustrated in FIG. 2 may also be used in the second polishing step, for example. The polishing conditions may be set within the above ranges.

### 3. Chemical Mechanical Polishing Aqueous Dispersion Preparation Kit

The chemical mechanical polishing aqueous dispersion may be supplied in a state in which the chemical mechanical polishing aqueous dispersion can be directly used as a polishing composition after preparation. Alternatively, a polishing composition containing each component of the chemical mechanical polishing aqueous dispersion at a high concentration (i.e. concentrated polishing composition) may be provided, and the concentrated polishing composition may be diluted before use to obtain a desired chemical mechanical polishing aqueous dispersion.

Alternatively, a plurality of compositions (e.g., two or three compositions) respectively containing at least one of the above components may be provided and mixed before use. In this case, a chemical mechanical polishing aqueous dispersion may be prepared by mixing a plurality of liquids, and supplied to the chemical mechanical polishing apparatus. Alternatively, a plurality of liquids may be individually supplied to the chemical mechanical polishing apparatus, and a chemical mechanical polishing aqueous dispersion may be prepared on the platen. For example, the chemical mechanical polishing aqueous dispersion may be prepared by mixing a plurality of liquids using the following first and second kits.

### 3.1 First Kit

The first kit is used to obtain the above chemical mechanical polishing aqueous dispersion by mixing a first composition and a second composition. The first composition of the first kit is an aqueous dispersion that includes the abrasive grains (C), the second composition of the first kit is an aqueous solution that includes the sulfonic acid group-containing water-soluble polymer (A) and the amino acid (B), and at least one of the first composition and the second composition includes the oxidizing agent (D).

When preparing the first composition and the second composition of the first kit, it is necessary to determine the concentration of each component contained in the first composition and the second composition so that each component is contained in an aqueous dispersion prepared by mixing the first composition and the second composition within the above concentration range. Each of the first composition and the second composition may contain each component at a high concentration (i.e. may be concentrated). In this case, the first composition and the second composition may be diluted before use. According to the first kit, the dispersion stability of the abrasive grains (C) contained in the first composition can be improved by separately preparing the first composition and the second composition.

When preparing the above chemical mechanical polishing aqueous dispersion by using the first kit, the first composition and the second composition may be mixed by an arbitrary method at an arbitrary timing insofar as the first composition and the second composition are prepared and supplied separately, and mixed before polishing. For example, the first composition and the second composition are prepared to contain each component at a concentration higher than that of the chemical mechanical polishing aqueous dispersion, diluted before use, and then mixed to obtain a chemical mechanical polishing aqueous dispersion in which the concentration of each component falls within the above range. Specifically, when mixing the first composition and the second composition in a weight ratio of 1:1, the first composition and the second composition are prepared so that the concentration of each component is twice that of the chemical mechanical polishing aqueous dispersion. Alternatively, the first composition and the second composition may be prepared so that the concentration of each component is equal to or more than twice that of the chemical mechanical polishing aqueous dispersion, and mixed in a weight ratio of 1:1. The mixture may be diluted with water so that the concentration of each component is within the above range.

When using the first kit, it suffices that the chemical mechanical polishing aqueous dispersion have been prepared before polishing. For example, the chemical mechanical polishing aqueous dispersion prepared by mixing the first composition and the second composition may be supplied to the chemical mechanical polishing apparatus, or the first composition and the second composition may be individually supplied to the chemical mechanical polishing apparatus, and mixed on the platen. Alternatively, the first composition and the second composition may be individually supplied to the chemical mechanical polishing apparatus, and mixed in a line of the chemical mechanical polishing apparatus, or mixed in a mixing tank provided in the chemical mechanical polishing apparatus. A line mixer or the like may be used to obtain a more uniform aqueous dispersion.

### 3.2 Second Kit

The second kit is used to obtain the above chemical mechanical polishing aqueous dispersion by mixing a third composition, a fourth composition, and a fifth composition. The third composition of the second kit is an aqueous dispersion that includes the abrasive grains (C), the fourth composition of the second kit is an aqueous solution that includes the sulfonic acid group-containing water-soluble polymer (A) and the amino acid (B), and the fifth composition is an aqueous solution that includes the oxidizing agent (D).

When preparing the third to fifth compositions of the second kit, it is necessary to determine the concentration of each component contained in the third to fifth compositions so that each component is contained in an aqueous dispersion prepared by mixing the third to fifth compositions within the above concentration range. Each of the third to fifth compositions may contain each component at a high concentration (i.e. may be concentrated). In this case, the third to fifth compositions may be diluted before use. According to the third kit, the dispersion stability of the abrasive grains (C) contained in the third composition and the storage stability of the oxidizing agent (D) contained in the fifth composition can be improved by separately preparing the third to fifth compositions.

When preparing the above chemical mechanical polishing aqueous dispersion by using the second kit, the third to fifth compositions may be mixed by an arbitrary method at an arbitrary timing insofar as the third to fifth compositions are prepared and supplied separately, and mixed before polishing. For example, the third to fifth compositions are prepared to contain each component at a concentration higher than that of the chemical mechanical polishing aqueous dispersion, diluted before use, and then mixed to obtain a chemical mechanical polishing aqueous dispersion in which the concentration of each component falls within the above range. Specifically, when mixing the third to fifth compositions in a weight ratio of 1:1:1, the third to fifth compositions are prepared so that the concentration of each component is twice that of the chemical mechanical polishing aqueous dispersion. Alternatively, the third to fifth compositions may be prepared so that the concentration of each component is equal to or more than three times that of the chemical mechanical polishing aqueous dispersion, and mixed in a weight ratio of 1:1:1. The mixture may be diluted with water so that the concentration of each component is within the above range.

When using the second kit, it suffices that the chemical mechanical polishing aqueous dispersion have been prepared before polishing. For example, the chemical mechanical polishing aqueous dispersion prepared by mixing the third to fifth compositions may be supplied to the chemical mechanical polishing apparatus, or the third to fifth compositions may be individually supplied to the chemical mechanical polishing apparatus, and mixed on the platen. Alternatively, the third to fifth compositions may be individually supplied to the chemical mechanical polishing apparatus, and mixed in a line of the chemical mechanical polishing apparatus, or mixed in a mixing tank provided in the chemical mechanical polishing apparatus. A line mixer or the like may be used to obtain a more uniform aqueous dispersion.

### 4. Examples

The invention is further described below by way of examples. Note that the invention is not limited to the following examples.

### 4.1 Synthesis of Water-Soluble Polymer

### (a) N-2-hydroxyethylacrylamide/2-acrylamide-2-methylpropanesulfonic acid copolymer

A separable flask was charged with 400 parts by mass of ion-exchanged water. The ion-exchanged water was heated to 65° C. with stirring, followed by the addition of 80 parts by mass of a 2.5% aqueous solution of 2,2′-azobis-2-methylpropioneamidine hydrochloride (“V50” manufactured by Wako Pure Chemical Industries, Ltd.). After the temperature of the mixture reached 75° C., a mixture of N-2-N-hydroxyethylacrylamide (120 parts by mass) and 20% 2-acrylamide-2-methylpropanesulfonic acid (400 parts by mass) was continuously added to the mixture over five hours. The temperature of the mixture was maintained at 75 to 80° C. After cooling the mixture, the weight average molecular weight (Mw) of the resulting water-soluble polymer was measured, and found to be 450,000 (PEG-reduced value).

### (b) Acryloylmorpholine-sodium allylsulfonate copolymer

A separable flask was charged with 400 parts by mass of ion-exchanged water. The ion-exchanged water was heated to 65° C. with stirring, followed by the addition of 80 parts by mass of a 2.5% ammonium persulfate aqueous solution. After the temperature of the mixture reached 75° C., a mixture of acryloylmorpholine (120 parts by mass) and 20% sodium allylsulfonate (400 parts by mass) was continuously added to the mixture over five hours. The temperature of the mixture was maintained at 75 to 80° C. After cooling the mixture, the weight average molecular weight (Mw) of the resulting water-soluble polymer was measured, and found to be 120,000 (PEG-reduced value).

### (c) Acrylamide-potassium styrenesulfonate copolymer

A separable flask was charged with 280 parts by mass of ion-exchanged water. The ion-exchanged water was heated to 65° C. with stirring, followed by the addition of 16 parts by mass of a 10% t-butyl hydroperoxide aqueous solution. After the temperature of the mixture reached 75° C., 3.8% sodium hydroxymethanesulfinate dihydrate (64 parts by mass) and a mixture of 50% acrylamide (240 parts by mass) and 20% potassium styrenesulfonate (400 parts by mass) were continuously added to the mixture over five hours. The temperature of the mixture was maintained at 75 to 80° C. After cooling the mixture, the weight average molecular weight (Mw) of the resulting water-soluble polymer was measured, and found to be 6000 (PEG-reduced value).

### (d) N-2-Hydroxyethylacrylamide-sodium allylsulfonate copolymer

A separable flask was charged with 400 parts by mass of ion-exchanged water. The ion-exchanged water was heated to 65° C. with stirring, followed by the addition of 80 parts by mass of a 5% ammonium persulfate aqueous solution. After the temperature of the mixture reached 75° C., a mixture of N-2-hydroxyethylacrylamide (120 parts by mass) and 20% sodium allylsulfonate (400 parts by mass) was continuously added to the mixture over five hours. The temperature of the mixture was maintained at 75 to 80° C. After cooling the mixture, the weight average molecular weight (Mw) of the resulting water-soluble polymer was measured, and found to be 16,500 (PEG-reduced value).

### (e) Acrylic acid-potassium styrenesulfonate copolymer

A separable flask was charged with 370 parts by mass of ion-exchanged water. The ion-exchanged water was heated to 65° C. with stirring, followed by the addition of 80 parts by mass of a 5% ammonium persulfate aqueous solution. After the temperature of the mixture reached 75° C., a mixture of 80% acrylic acid (150 parts by mass) and 20% potassium styrenesulfonate (400 parts by mass) was continuously added to the mixture over five hours. The temperature of the mixture was maintained at 75 to 80° C. After cooling the mixture, the weight average molecular weight (Mw) of the resulting water-soluble polymer was measured, and found to be 52,000 (PEG-reduced value).

### (f) Poly(sodium allylsulfonate)

A separable flask was charged with 520 parts by mass of ion-exchanged water. The ion-exchanged water was heated to 65° C. with stirring, followed by the addition of 80 parts by mass of a 5% ammonium persulfate aqueous solution. After the temperature of the mixture reached 75° C., 20% sodium allylsulfonate (1000 parts by mass) was continuously added to the mixture over five hours. The temperature of the mixture was maintained at 75 to 80° C. After cooling the mixture, the weight average molecular weight (Mw) of the resulting water-soluble polymer was measured, and found to be 1500 (PEG-reduced value).

### (g) Poly(sodium allylsulfonate)

A separable flask was charged with 560 parts by mass of ion-exchanged water. The ion-exchanged water was heated to 65° C. with stirring, followed by the addition of 40 parts by mass of a 5% ammonium persulfate aqueous solution. After the temperature of the mixture reached 75° C., 20% sodium allylsulfonate (1000 parts by mass) was continuously added to the mixture over five hours. The temperature of the mixture was maintained at 65 to 75° C. After cooling the mixture, the weight average molecular weight (Mw) of the resulting water-soluble polymer was measured, and found to be 5500 (PEG-reduced value).

### (h) Polyvinylsulfonic acid

A separable flask was charged with 720 parts by mass of ion-exchanged water. The ion-exchanged water was heated to 65° C. with stirring, followed by the addition of 80 parts by mass of a 5% ammonium persulfate aqueous solution. After the temperature of the mixture reached 75° C., vinylsulfonic acid (200 parts by mass) was continuously added to the mixture over five hours. The temperature of the mixture was maintained at 65 to 75° C. After cooling the mixture, the weight average molecular weight (Mw) of the resulting water-soluble polymer was measured, and found to be 18,000 (PEG-reduced value).

The following commercially available products were used as other water-soluble polymers.

(i) Sulfonated styrene-isoprene copolymer (Mw=20,000, “Dynaflow DK106” manufactured by JSR Corporation)
(j) Poly(sodium styrenesulfonate) (Mw=70,000, available from Wako Pure Chemical Industries, Ltd.)
(k) Poly(sodium styrenesulfonate) (Mw=1,000,000, available from Wako Pure Chemical Industries, Ltd.)
(l) Polyacrylic acid (Mw=250,000, available from Wako Pure Chemical Industries, Ltd.)
(m) Polyvinyl alcohol (degree of polymerization: 1000, partially saponified product, available from Wako Pure Chemical Industries, Ltd.)
(n) Polyvinylpyrrolidone (Mw=35,000, available from Wako Pure Chemical Industries, Ltd.)
(o) Polyacrylamide (Mw=500,000, available from Wako Pure Chemical Industries, Ltd.)

The names and the molecular weights of the water-soluble polymers are listed in Table 1.

TABLE 1

| | | Weight average |
|---|---|---|
| Sym- | | molecular weight |
| bol | Water-soluble polymer | (Mw) |
| (a) | N-2-Hydroxyethylacrylamide-2-acrylamide- | 450,000 |
| | 2-methylpropanesulfonic acid copolymer | |
| (b) | Acryloylmorpholine-sodium allylsulfonate | 120,000 |
| | copolymer | |
| (c) | Acrylamide-potassium styrenesulfonate | 6,000 |
| | copolymer | |
| (d) | N-2-Hydroxyethylacrylamide-sodium | 16,500 |
| | allylsulfonate copolymer | |
| (c) | Acrylic acid-potassium styrenesulfonate | 52,000 |
| | copolymer | |
| (f) | Poly(sodium allylsulfonate) | 1,500 |
| (g) | Poly(sodium allylsulfonate) | 5,500 |
| (h) | Polyvinylsulfonic acid | 18,000 |
| (i) | Sulfonated styrene-isoprene copolymer | 20,000 |
| (j) | Poly(sodium styrenesulfonate) | 70,000 |
| (k) | Poly(sodium styrenesulfonate) | 1,000,000 |
| (l) | Polyacrylic acid | 250,000 |
| (m) | Polyvinyl alcohol | Degree of poly- |
| | | merization: 1000/ |
| | | partially saponified |
| | | product |
| (n) | Polyvinylpyrrolidone | 35,000 |
| (o) | Polyacrylamide | 500,000 |

### 4.2 Preparation of Aqueous Dispersion Containing Colloidal Silica Particles

A flask was charged with 70 parts by mass of 25 mass % aqueous ammonia, 40 parts by mass of ion-exchanged water, 170 parts by mass of ethanol, and 20 parts by mass of tetraethoxysilane. The mixture was heated to 60° C. with stirring at a rotational speed of 180 rpm. The mixture was stirred at 60° C. for two hours to obtain an alcohol dispersion of colloidal silica particles.

After the addition of ion-exchanged water, the alcohol component was removed by using a rotary evaporator to obtain an aqueous dispersion C30 containing 20 mass % of colloidal silica particles. The average primary particle diameter of the colloidal silica particles contained in the aqueous dispersion determined using a transmission electron microscope was 30 nm. The average secondary particle diameter of the colloidal silica particles determined using a dynamic light scattering particle size analyzer (“HORIBA LB550” manufactured by Horiba Ltd.) was 65 nm.

An aqueous dispersion C35 containing 20 mass % of colloidal silica particles (average primary particle diameter: 35 nm, average secondary particle diameter: 70 nm) and an aqueous dispersion C50 containing 20 mass % of colloidal silica particles (average primary particle diameter: 50 nm, average secondary particle diameter: 120 nm) were prepared in the same manner as described above, except for changing the amounts of aqueous ammonia, ethanol, and tetraethoxysilane and the temperature employed during stirring.

### 4.3 Examples 1 to 14 and Comparative Examples 1 to 7

### 4.3.1 Preparation of Chemical Mechanical Polishing Aqueous Dispersion

### (a) Example 1

A polyethylene bottle was charged with 0.3 mass % (solid content) of the colloidal silica aqueous dispersion C35 (the amount of each component is based on the mass (100 mass %) of the chemical mechanical polishing aqueous dispersion). After the addition of 0.5 mass % of alanine, 0.5 mass % (ammonia content) of 28% aqueous ammonia, 0.1 mass % (solid content) of ammonium dodecylbenzenesulfonate, 0.05 mass % (solid content) of a N-2-hydroxyethylacrylamide-2-acrylamide-2-methylpropanesulfonic acid copolymer (weight average molecular weight (Mw)=450,000), and 0.2 mass % of 30 mass % of aqueous hydrogen peroxide, ion-exchanged water was added so that the total amount of the components was 100 mass %. The mixture was stirred for one hour. The mixture was then filtered through a filter having a pore size of 5 micrometers to obtain a chemical mechanical polishing aqueous dispersion of Example 1 (see Table 2).

### (b) Examples 2 to 14 and Comparative Examples 1 to 7

A chemical mechanical polishing aqueous dispersion of each example was prepared in the same manner as described above, except for changing the type of water-soluble polymer and the additional components as shown in Tables 2 to 4. In Examples 13 and 14, two types of water-soluble polymers were added at concentrations shown in Table 3.

In Tables 2 to 4, “Pelex NB-L” is a surfactant having a sodium alkylnaphthalenesulphonate structure manufactured by Kao Corporation, “Pelex OT-P” is a surfactant having a sodium alkylsulfosuccinate structure manufactured by Kao Corporation, and “Emulgen 1135S-70” is a surfactant having a polyoxyethylene alkyl ether structure manufactured by Kao Corporation. “Pelex NB-L” and “Pelex OT-P” are anionic surfactants, and “Emulgen 1135S-70” is a nonionic surfactant.

### 4.3.2 Evaluation of Copper Film Removal Rate

A porous polyurethane polishing pad (“IC” manufactured by Rohm and Haas) was installed in a chemical mechanical polishing apparatus (“Mirra-Mesa” manufactured by Applied Materials, Inc.,). A removal rate measurement substrate was polished for one minute under the following polishing conditions while supplying the dispersion prepared as described above. The removal rate of the copper film was calculated by the following method. The removal rate of the copper film is preferably 8000 angstroms/min or more, and more preferably 10,000 angstroms/min or more.

### (a) Removal Rate Measurement Substrate

Eight-inch silicon substrate with thermal oxide film on which a copper film having a thickness of 15,000 angstroms was formed

### (b) Polishing Conditions

Head rotational speed: 90 rpm

Table rotational speed: 90 rpm

Head load: 105 g/cm²

Supply rate of chemical mechanical polishing aqueous dispersion: 200 ml/min

### (c) Calculation of Removal Rate

The sheet resistance of the polished metal film was measured by a direct-current four-point probe method using a resistivity meter (“S-5” manufactured by NPS Inc.), and the thickness of the metal film was measured by the following expression. The removal rate was calculated from the thickness reduced by chemical mechanical polishing and the endpoint time.

Thickness of metal film(angstrom)=sheet resistance(ohm/cm²)/theoretical resistivity of metal(ohm/cm)×10⁸

### 4.3.3 Evaluation of Copper Film Polishing Performance

A patterned wafer (“SEMATECH 854” manufactured by SEMATECH INTERNATIONAL, copper film polishing test substrate having various wiring patterns) was chemically and mechanically polished in the same manner as in “4.3.2 Evaluation of copper film removal rate”, except that the polishing time was set to be 1.3 times the time from the polishing start time to the end point detected from a change in table torque current. Residual copper on the minute wiring pattern as well as dishing, erosion, and corrosion of the copper interconnect were evaluated by the following methods.

### (a) Evaluation of Residual Copper

The thickness of copper remaining in an area where a pattern in which a wiring area (width: 0.18 micrometers, length: 1.6 mm) and an insulating area (width: 0.18 micrometers, length: 1.6 mm) were alternately provided was formed to a length of 1.25 mm in the direction perpendicular to the longitudinal direction, was measured by using a precision step meter (“HRP-240” manufactured by KLA-Tencor Corporation). A case where no copper remained is indicated by “Good” in Tables 2 to 4. A case where copper remained on some of the patterns is indicated by “Fair” in Tables 2 to 4. A case where copper remained on all of the patterns is indicated by “Bad” in Tables 2 to 4.

### (b) Evaluation of Dishing

The term “dishing” used herein refers to the distance (difference in height) between the upper side (i.e., a plane formed by the insulating film or the conductive barrier metal film) of the wafer and the lowest area of the wiring area. The amount of dishing of a copper interconnect with a width of 100 micrometers in an area where a pattern in which a wiring area (width: 100 micrometers, length: 3.0 mm) and an insulating area (width: 100 micrometers, length: 3.0 mm) were alternately provided was formed to a length of 3.0 mm in the direction perpendicular to the longitudinal direction, was measured by using a precision step meter (“HRP-240” manufactured by KLA-Tencor Corporation). The results are shown in Tables 2 to 4. The amount of dishing is preferably 1000 angstroms or less, and more preferably 500 angstroms or less.

### (c) Evaluation of Erosion

The amount of erosion of the center of an interconnect with respect to the ends in an area where a pattern in which a copper interconnect area with a width of 9 micrometers and an insulating area with a width of 1 micrometer were alternately provided was continuously formed to a length of 1.25 mm in the longitudinal direction was measured by using a precision step meter (“HRP-240” manufactured by KLA-Tencor Corporation). The results are shown in Tables 2 to 4. The amount of erosion is preferably 500 angstroms or less, and more preferably 250 angstroms or less.

### (d) Evaluation of Corrosion

The number of defects with a size of 10 to 100 nm2 in a 1×1 cm copper area was determined by using a defect inspection instrument (“2351” manufactured by KLA-Tencor Corporation). In Tables 2 to 4, a case where the number of defects (corrosion) was 0 to 10 is indicated by “Good”. A case where the number of defects (corrosion) was 11 to 100 is indicated by “Fair”. A case where the number of defects (corrosion) was 101 or more is indicated by “Bad”.

Table 2 shows the composition of the chemical mechanical polishing aqueous dispersions used in Examples 1 to 7 and the evaluation results for copper film polishing performance.

TABLE 2

| | | Example 1 | Example 2 | Example 3 | Example 4 | Example 5 | Example 6 | Example 7 |
|---|---|---|---|---|---|---|---|---|
| Water-soluble | Type | (a) | (g) | (h) | (b) | (c) | (d) | (i) |
| polymer | Concentration | 0.05 | 0.5 | 0.5 | 0.15 | 0.3 | 0.5 | 0.1 |
| | (mass %) | | | | | | | |
| Oxidizing agent | Type | Hydrogen | Hydrogen | Hydrogen | Hydrogen | Ammonium | Hydrogen | Hydrogen |
| | | peroxide | peroxide | peroxide | peroxide | peroxide | peroxide | peroxide |
| | Concentration | 0.2 | 0.2 | 0.1 | 0.3 | 1.0 | 0.2 | 0.5 |
| | (mass %) | | | | | | | |
| Amino acid | Type | Alanine | Glycine | Glycine | Glycine | Aspartic acid | Glycine | Alanine |
| | Concentration | 0.5 | 1.2 | 0.8 | 0.5 | 1.0 | 0.8 | 1.0 |
| | (mass %) | | | | | | | |
| Abrasive grains | Type | Colloidal | Colloidal | Colloidal | Colloidal | Colloidal | Colloidal | Colloidal |
| | | silica | silica | silica | silica | silica | silica | silica |
| | | C35 | C30 | C30 | C35 | C50 | C30 | C30 |
| | Concentration | 0.3 | 0.5 | 0.3 | 1.0 | 0.3 | 0.5 | 1.0 |
| | (mass %) | | | | | | | |
| Surfactant | Type | Ammonium | Pelex NB-L | Pelex NB-L | Pelex OT-P | Ammonium | Ammonium | Ammonium |
| | | dodecyl- | | | | dodecyl- | dodecyl- | dodecyl- |
| | | benzene- | | | | benzene- | benzene- | benzene- |
| | | sulfonate | | | | sulfonate | sulfonate | sulfonate |
| | Concentration | 0.1 | 0.2 | 0.2 | 0.5 | 0.05 | 0.08 | 0.05 |
| | (mass %) | | | | | | | |
| pH | | 9.9 | 9.8 | 10.2 | 9.0 | 9.5 | 9.7 | 9.6 |
| Removal rate (angstroms/min) | | 8600 | 14215 | 12900 | 8340 | 8560 | 10490 | 11600 |
| Planarity | Dishing | 420 | 620 | 580 | 395 | 605 | 385 | 505 |
| | (angstroms) | | | | | | | |
| | Erosion | 110 | 280 | 225 | 260 | 175 | 180 | 260 |
| | (angstroms) | | | | | | | |

| | | | | | | | |
|---|---|---|---|---|---|---|---|
| Residual Cu | Fair | Good | Good | Fair | Good | Good | Good |
| Cu surface state (corrosion) | Good | Fair | Good | Good | Good | Good | Good |

Table 3 shows the composition of the chemical mechanical polishing aqueous dispersions used in Examples 8 to 14 and the evaluation results for copper film polishing performance.

TABLE 3

| | | Example 8 | Example 9 | Example 10 | Example 11 | Example 12 | Example 13 | Example 14 |
|---|---|---|---|---|---|---|---|---|
| Water- | Type | (k) | (j) | (f) | (j) | (e) | (j)/(o) | (j)/(n) |
| soluble | Concentration | 0.2 | 1.8 | 0.8 | 0.0015 | 0.2 | 0.2/0.3 | 0.2/0.3 |
| polymer | (mass %) | | | | | | | |
| Oxidizing | Type | Hydrogen | Hydrogen | Hydrogen | Hydrogen | Hydrogen | Hydrogen | Hydrogen |
| agent | | peroxide | peroxide | peroxide | peroxide | peroxide | peroxide | peroxide |
| | Concentration | 0.3 | 0.3 | 0.2 | 0.2 | 0.2 | 0.2 | 0.2 |
| | (mass %) | | | | | | | |
| Amino acid | Type | Alanine | Alanine | Alanine | Glycine | Alanine | Alanine | Alanine |
| | Concentration | 0.8 | 1.8 | 0.5 | 0.8 | 0.5 | 0.5 | 0.5 |
| | (mass %) | | | | | | | |
| Abrasive | Type | Colloidal | Colloidal | Colloidal | Colloidal | Colloidal | Colloidal | Colloidal |
| grains | | silica C35 | silica C35 | silica C50 | silica C30 | silica C50 | silica C50 | silica C50 |
| | Concentration | 0.5 | 0.5 | 0.2 | 0.3 | 0.2 | 0.2 | 0.2 |
| | (mass %) | | | | | | | |
| Surfactant | Type | Ammonium | Ammonium | Sodium | Pelex | Pelex | Ammonium | Ammonium |
| | | dodecylbenzene- | dodecylbenzene- | lauryl- | NB-L | OT-P | dodecylbenzene- | dodecylbenzene- |
| | | sulfonate | sulfonate | sulfate | | | sulfonate | sulfonate |
| | Concentration | 0.02 | 0.5 | 0.2 | 0.05 | 0.005 | 0.1 | 0.1 |
| | (mass %) | | | | | | | |
| pH | | 9.6 | 9.6 | 9.8 | 9.7 | 9.8 | 9.8 | 9.9 |
| Removal rate | | 8450 | 8010 | 9430 | 12320 | 13100 | 8230 | 8560 |
| (angstroms/min) | | | | | | | | |
| Planarity | Dishing | 310 | 285 | 910 | 865 | 810 | 695 | 630 |
| | (angstroms) | | | | | | | |
| | Erosion | 95 | 110 | 590 | 610 | 715 | 280 | 245 |
| | (angstroms) | | | | | | | |

| | | | | | | | |
|---|---|---|---|---|---|---|---|
| Residual Cu | Fair | Fair | Good | Good | Good | Good | Good |
| Cu surface state (corrosion) | Good | Good | Fair | Fair | Fair | Good | Fair |

Table 4 shows the composition of the chemical mechanical polishing aqueous dispersions used in Comparative Examples 1 to 7 and the evaluation results for copper film polishing performance.

TABLE 4

| | | Comparative | Comparative | Comparative | Comparative | Comparative | Comparative | Comparative |
|---|---|---|---|---|---|---|---|---|
| | | Example 1 | Example 2 | Example 3 | Example 4 | Example 5 | Example 6 | Example 7 |
| Water-soluble | Type | (m) | (l) | (l) | — | (l) | (l) | (l) |
| polymer | Concentration | 0.5 | 0.1 | 0.1 | — | 0.1 | 0.1 | 0.1 |
| | (mass %) | | | | | | | |
| Oxidizing | Type | Hydrogen | Hydrogen | Hydrogen | Hydrogen | Hydrogen | Hydrogen | — |
| agent | | peroxide | peroxide | peroxide | peroxide | peroxide | peroxide | |
| | Concentration | 0.3 | 0.2 | 0.2 | 0.2 | 0.2 | 0.2 | — |
| | (mass %) | | | | | | | |
| Amino acid | Type | Glycine | Glycine | Glycine | Glycine | — | Glycine | Glycine |
| | Concentration | 0.5 | 0.5 | 0.5 | 0.5 | — | 0.5 | 0.5 |
| | (mass %) | | | | | | | |
| Abrasive | Type | Colloidal | Colloidal | Colloidal | Colloidal | Colloidal | — | Colloidal |
| grains | | silica C35 | silica C35 | silica C35 | silica C35 | silica C35 | | silica C35 |
| | Concentration | 0.5 | 0.5 | 0.5 | 0.5 | 0.5 | — | 0.5 |
| | (mass %) | | | | | | | |
| Surfactant | Type | Ammonium | Pelex NB-L | Emulgen | Pelex NB-L | Pelex NB-L | Pelex NB-L | Pelex NB-L |
| | | dodecylbenzene- | | 1135S-70 | | | | |
| | | sulfonate | | | | | | |
| | Concentration | 0.03 | 0.1 | 0.1 | 0.1 | 0.1 | 0.1 | 0.1 |
| | (mass %) | | | | | | | |
| pH | | 10.0 | 9.6 | 9.6 | 9.8 | 10.6 | 9.8 | 9.8 |
| Removal rate (angstroms/min) | | 12600 | 11450 | 8540 | 12850 | Polishing | Polishing | Polishing |
| | | | | | | failure | failure | failure |
| Planarity | Dishing | 2800 | 2250 | 3550 | 4800 | Could not be | Could not be | Could not be |
| | (angstroms) | | | | | evaluated | evaluated | evaluated |
| | Erosion | 480 | 965 | 825 | 2650 | Could not be | Could not be | Could not be |
| | (angstroms) | | | | | evaluated | evaluated | evaluated |

| | | | | | | | |
|---|---|---|---|---|---|---|---|
| Residual Cu | Good | Good | Good | Good | Could not be | Could not be | Could not be |
| | | | | | evaluated | evaluated | evaluated |
| Cu surface state (corrosion) | Fair | Bad | Bad | Bad | Could not be | Could not be | Could not be |
| | | | | | evaluated | evaluated | evaluated |

In Tables 2 to 4, the water-soluble polymer is indicated by the symbol shown in Table 1.

As shown in Tables 2 and 3, when using the chemical mechanical polishing aqueous dispersions of Examples 1 to 14, occurrence of residual copper, dishing, and erosion of the polishing substrate surface was significantly reduced when chemically and mechanically polishing the copper film formed on the semiconductor substrate. Moreover, occurrence of surface defects such as corrosion was also reduced. Therefore, a sufficiently and accurately planarized polished surface could be obtained.

When using the chemical mechanical polishing aqueous dispersions of Comparative Examples 1 to 3 (examples in which a water-soluble polymer that did not contain a sulfonic acid group was used), dishing and erosion occurred to a large extent. Moreover, corrosion was also observed. When using the chemical mechanical polishing aqueous dispersion of Comparative Example 4 (example in which a water-soluble polymer was used), dishing and erosion occurred to a larger extent as compared with Comparative Examples 1 to 3. Moreover, corrosion was also observed. The above results suggest that dishing and erosion can be significantly reduced while reducing corrosion by utilizing the sulfonic acid group-containing water-soluble polymer.

When using the chemical mechanical polishing aqueous dispersion of Comparative Example 5 (example in which a water-soluble polymer that did not contain a sulfonic acid group was used, and an amino acid was not used), the removal rate decreased to a large extent (the endpoint time could not be set). Therefore, the chemical mechanical polishing aqueous dispersion of Comparative Example 5 cannot be used in practical applications.

When using the chemical mechanical polishing aqueous dispersion of Comparative Example 6 (example in which a water-soluble polymer that did not contain a sulfonic acid group was used, and abrasive grains were not used), the removal rate decreased to a large extent (the endpoint time could not be set). Therefore, the chemical mechanical polishing aqueous dispersion of Comparative Example 6 cannot be used in practical applications.

When using the chemical mechanical polishing aqueous dispersion of Comparative Example 7 (example in which a water-soluble polymer that did not contain a sulfonic acid group was used, and an oxidizing agent was not used), the copper film could not be oxidized, and the removal rate decreased to a large extent (the endpoint time could not be set). Therefore, the chemical mechanical polishing aqueous dispersion of Comparative Example 7 cannot be used in practical applications.

The above results suggest that a chemical mechanical polishing aqueous dispersion that exhibits excellent copper polishing performance can be obtained by utilizing the amino acid, abrasive grains, and oxidizing agent in combination with the sulfonic acid group-containing water-soluble polymer.

1. A chemical mechanical polishing aqueous dispersion comprising (A) a water-soluble polymer comprising a sulfonic acid group, (B) an amino acid, (C) an abrasive grain, and (D) an oxidizing agent.

2. The chemical mechanical polishing aqueous dispersion according to claim 1, further comprising (E) an anionic surfactant.

3. The chemical mechanical polishing aqueous dispersion according to claim 1, wherein the water-soluble polymer comprising a sulfonic acid group (A) is a copolymer that comprises a repeating unit derived from a monomer comprising a sulfonic acid group, and a repeating unit derived from a monomer comprising an amide group.

4. The chemical mechanical polishing aqueous dispersion according to claim 3, wherein the monomer comprising a sulfonic acid group is selected from isoprenesulfonic acid, styrenesulfonic acid, vinylsulfonic acid, allylsulfonic acid, methallylsulfonic acid, 3-sulfopropyl acrylate, 3-sulfopropyl methacrylate, 2-acrylamide-methylpropanesulfonic acid, and salts thereof.

5. The chemical mechanical polishing aqueous dispersion according to claim 3, wherein the monomer comprising an amide group is selected from (meth)acrylamide, N-methylolacrylamide, N-2-hydroxyethylacrylamide, acryloylmorpholine, dimethylaminopropylacrylamide, N,N-dimethylacrylamide, N-isopropylacrylamide, N-vinylacetamide, and N-vinylformamide.

6. The chemical mechanical polishing aqueous dispersion according to claim 1, wherein the water-soluble water-soluble polymer comprising a sulfonic acid group (A) has a weight average molecular weight of 5000 to 500,000.

7. A chemical mechanical polishing aqueous dispersion preparation kit comprising a first composition and a second composition, the first composition including (C) an abrasive grain, the second composition including (A) a water-soluble polymer comprising a sulfonic acid group and (B) an amino acid, and at least one of the first composition and the second composition including (D) an oxidizing agent.

8. A chemical mechanical polishing aqueous dispersion preparation kit comprising a third composition, a fourth composition, and a fifth composition, the third composition including (C) an abrasive grain, the fourth composition including (A) a water-soluble polymer comprising a sulfonic acid group and (B) an amino acid, and the fifth composition including (D) an oxidizing agent.

9. A method of preparing a chemical mechanical polishing aqueous dispersion, the method comprising mixing the compositions of the chemical mechanical polishing aqueous dispersion preparation kit according to claim 8.

10. A chemical mechanical polishing method for a semiconductor device, the method comprising polishing a copper or copper alloy film formed on a semiconductor substrate by using the chemical mechanical polishing aqueous dispersion according to claim 1.

11. A method of preparing a chemical mechanical polishing aqueous dispersion, the method comprising mixing the compositions of the chemical mechanical polishing aqueous dispersion preparation kit according to claim 7.

12. A chemical mechanical polishing method for a semiconductor device, the method comprising polishing a copper or copper alloy film formed on a semiconductor substrate by using a chemical mechanical polishing aqueous dispersion prepared by mixing the compositions of the chemical mechanical polishing aqueous dispersion preparation kit according to claim 7.

13. A chemical mechanical polishing method for a semiconductor device, the method comprising polishing a copper or copper alloy film formed on a semiconductor substrate by using a chemical mechanical polishing aqueous dispersion prepared by mixing the compositions of the chemical mechanical polishing aqueous dispersion preparation kit according to claim 8.
